(19) United States
(12) Patent Application Publication
(10) Pub. No.: US 2025/0131825 A1
(43) Pub. Date: Apr. 24, 2025

(54) Decentralized fleet control system and decentralized fleet control device

(71) Applicants: ETO GRUPPE TECHNOLOGIES GmbH, Stockach (DE); Swarm Logistics GmbH, Stuttgart (DE)

(72) Inventors: Benjamin Bönisch, Bodman-Ludwigshafen (DE); Tobias Plötzing, Bodman-Ludwigshafen (DE); Harry Trautmann, Metzingen (DE); Damir Dulovic, Fellbach (DE)

(21) Appl. No.: 18/689,781

(22) PCT Filed: Sep. 7, 2022
(86) PCT No.: PCT/EP2022/074904

§ 371 Date: Mar. 6, 2024

(30) Foreign Application Priority Data
Sep. 8, 2021 (DE) 10 2021 123 194.9

(51) Int. Cl. G08G 1/16; G06F 30/27; G06Q 50/40; H04W 4/46

(52) U.S. Cl. CPC G08G 1/161; G06F 30/27; G06Q 50/40; H04W 4/46

(57) ABSTRACT

A decentralized control system for the intra-fleet and/or inter-fleet, at least partially self-organized, control of a network formed at least by vehicles comprises a decentralized consensus module, which is designed for transmitting mobility orders, in particular network-external or network-internal transport orders or service provision orders, and/or mobility offers, in particular transport offers or service provision offers, of vehicles of the network, in each case in the form of smart contracts within a distributed ledger technology (DLT), such as a directed acyclic graph (e.g. an IOTA tangle) or a blockchain, to more than one terminal, the terminals being respectively assigned to vehicles of the network.

### PRIOR ART

The invention relates to a decentralized control system according to the preamble of claim 1 and to a decentralized control method according to the preamble of claim 14.

Digital logistics control systems have already been proposed, which, however, typically comprise central server structures for the organization of network subscribers. In these, decisions taken centrally are only communicated to the individual network subscribers for implementation.

The object of the invention is in particular to provide a generic device which has improved properties with regard to efficiency. The object is achieved according to the invention by the features of claims 1 and 14, while advantageous embodiments and further developments of the invention can be derived from the subclaims.

### ADVANTAGES OF THE INVENTION

The invention proceeds from a decentralized control system for the intra-fleet and/or inter-fleet, at least partially self-organized, control of a network formed at least by vehicles, in particular by passenger transport vehicles, goods transport and/or service vehicles.

It is proposed that the decentralized control system has a decentralized consensus module, which is designed to transmit mobility orders, in particular network-external or network-internal transport orders or service provision orders, and/or mobility offers, in particular transport offers or service provision offers of vehicles of the network, in each case in the form of smart contracts within a distributed ledger technology (DLT), for example as a directed acyclic graph (e.g. an IOTA tangle) or a (public or private) blockchain, to more than one terminal, the terminals being respectively assigned to vehicles of the network. This allows a high efficiency, in particular control efficiency of the vehicle network, to be advantageously achieved. Optimum utilization of the vehicles of the network can be advantageously achieved. A high level of security of the control system can be advantageously achieved. For example, the effort involved in significantly impairing the proper functioning of the entire network, e.g. by cyber-attacks such as DDoS hacking attacks, is a practical impossibility. Even if individual vehicles in the network were to be attacked in this way, the rest of the network would advantageously remain fully functional. In such a case, unaffected vehicles in the network could advantageously assume the tasks of the affected vehicle, e.g. the mobility orders, in a self-organized manner. The DLT advantageously guarantees the integrity of the transactions of the decentralized control system. Advantageously, the DLT replaces a central coordinator. The term “designed” is to be understood, in particular, to mean specially programmed, configured and/or equipped. The fact that an object is designed for a specific function is intended to mean in particular that the object fulfils and/or performs this specific function in at least one application state and/or operating state.

A “fleet” is to be understood, in particular, as the totality of the vehicles (vehicle pool), in particular the transport vehicles, of an organization or a company, in particular a logistics company or a service provision company. In particular, it is conceivable that multiple fleets are assigned to the decentralized control system or form parts of the vehicle network organized by the decentralized control system. In particular, an “intra-fleet control” is to be understood as a control of vehicles belonging to an individual transport fleet. In particular, an “inter-fleet control” is to be understood as a common control of vehicles belonging to multiple different vehicle pools/different transport fleets. In particular, the decentralized control system can be structured in two stages, so that mobility orders, in particular transport orders or service provision orders, and/or mobility offers, in particular transport offers or service provision offers of vehicles of the network, are first distributed within a fleet. In this case, if the respective mobility order or offer is not accepted or would only be accepted under unsatisfactory conditions, the mobility order or mobility offer is transmitted at an inter-fleet level to vehicles of other fleets connected to the network. In particular, there may be at least two distinct categories of smart contracts which are transmitted via the consensus module, wherein in a first category, participation in the smart contract is restricted to collaborating vehicles of a common fleet or to collaborating fleets, and wherein in a second category, competing vehicles of other fleets or competing fleets are also included. Each new mobility order is prepared as a new smart contract, which can be defined as one of the two categories, in particular at the time it is prepared.

The vehicles may be in particular formed by land vehicles, preferably rail or road vehicles, watercraft, aircraft or spacecraft. In particular, the passenger and/or freight transport vehicle is intended not only to transport the vehicle driver (driver, flight captain, captain, train driver), but is also used for transporting goods (freight) and/or passengers. For example, the goods transport vehicle is in the form of a car, a truck, a bus, a van, a motorized two-or three-wheeled cycle (moped, e-bike, pedelec, e-cargo bike, etc.), a non-motorized two-or three-wheeled cycle (bicycle, cargo bike, etc.), a delivery robot, a storage robot or the like from an intralogistics environment, a freight train, a passenger train, a cargo ship, a passenger ship, a cargo plane, a passenger plane, etc. In particular, the vehicles may be manned or unmanned (autonomously driven). In particular, the vehicles of the network form a cluster of vehicles, in particular self-organizing ones. In particular, the transmission of mobility orders and/or mobility offers and the acceptance of mobility orders and/or mobility offers (also) takes place while the network is active, i.e. in particular while at least a subset of all vehicles of the network is traveling/on the move. In particular, the service vehicle is designed as a vehicle that is used to offer or perform a service at different locations. The service vehicle can be in the form, for example, of a waste collection vehicle, a road cleaning vehicle, a snow clearing vehicle, a towing vehicle, a street trading vehicle (ice cream van, bakery wagon, etc.), a police vehicle, an emergency service vehicle, a taxi, a construction machine, as a service engineer's vehicle, a tradesperson's vehicle or the like.

A “network-external order” is, in particular, an order that is placed externally (by an entity not connected to the network) in the decentralized control system. A “network-internal order” is, in particular, an order that is placed internally (by an entity connected to the network) in the decentralized control system. In particular, a mobility order shall comprise a request to move goods or persons between specified locations or a request to provide a service at a specified location. The mobility order may include, for example, a request to move at least one corresponding vehicle to a specific location, where it is to accept or deliver goods or persons or to offer or perform a service. Mobility orders are placed in the decentralized control system by external interested parties or by the vehicles themselves. A mobility offer shall comprise, in particular, an offer by a vehicle to move goods or people between specific locations or to perform services at specific locations. Mobility offers are placed in the decentralized control system by the vehicles themselves. In particular, a “Smart Contract” is a transaction record that is intended to automatically execute, control or document legally relevant events and actions under the terms of a contract or agreement. In particular, the smart contract implements a contract settlement, i.e. determines a consensus on mobility demand (mobility order) and vehicle offer (responding offer), on the terms under which agreements are ultimately concluded. Advantageously, the use of smart contracts can reduce the need for trusted intermediaries. In addition, implementation and enforcement costs can be advantageously reduced. In addition, a high level of automation of contract negotiations can be achieved. Moreover, a high degree of flexibility in contract negotiations can be advantageously achieved. In addition, a high degree of security against the failure of contract negotiations can be advantageously achieved. In particular, the distributed ledger of the DLT is designed to manage states of the smart contracts of the decentralized control system. In particular, only one terminal at a time is assigned to a vehicle of the network. In particular, the vehicles of the vehicle network are networked with each other via wireless and radio communication technology, for example via a cellular radio connection, an encrypted Internet connection or the like. In particular, communication between the vehicles of the network, in particular the decentralized consensus module, and external systems from which mobility orders, etc. can be imported, takes place via an encrypted (wireless) Internet connection. In particular, each terminal comprises a wireless communication device or is connected to another wireless communication device of the vehicle or the driver.

It is also proposed that each vehicle in the network, in particular in the decentralized control system, be represented by a digital twin. This advantageously enables the vehicles of the network to be represented as independent economic participants in a Machine Economy. For example, the vehicles are advantageously placed in a position to conduct negotiations with other network-external vehicles, e.g. vehicles from an intralogistics (AGVs, warehouse robots, etc.), e.g. about transshipment times, transshipment locations, transport charges, etc. The vehicles of the network can be advantageously integrated with intralogistics vehicles or other digital twins of machines within the machine economy. The term “digital twin” is intended to mean in particular a digital representation of a material or immaterial object from the real world (here: a vehicle) in the digital world (here: decentralized control system). Digital twins are preferably more than pure data and consist of models of the represented object and may also contain simulations, algorithms and services that describe, manipulate, or offer services related to the properties or behavior of the represented object.

Furthermore, it is proposed that each digital twin is an autonomous decision-making agent in a multi-agent system (MAS, sometimes also called multi-robot system or distributed artificial intelligence), wherein the multi-agent system is formed at least by the totality of the digital twins each representing vehicles of the network and of their interaction/communication with one another. Thus, a self-organized dynamic, efficient and resilient management and/or coordination of the mobility orders and/or the mobility offers can be advantageously achieved. Other network-external agents are conceivable.

It is also proposed that each terminal, in particular each vehicle, preferably each digital twin, is assigned a separate decision module which is designed to prepare at least one responding offer, in particular an offer that can be assigned to the digital twin of the corresponding vehicle, in response to at least one received mobility order and preferably to transmit said offer to the consensus module in an automated manner. This makes it possible advantageously to achieve an efficient self-organized management/coordination of the mobility orders. Optimal fulfillment of mobility orders can thus be achieved in an advantageous manner. For example, transport times, routes and/or costs can be minimized. In particular, the decision module prepares the responding offer. In particular, the generated responding offer is then transmitted from the decision module to the consensus module. In particular, the consensus module receives one or more responding offers from different terminals for each mobility offer. In particular, before preparing the responding offer, the decision module weighs up whether to prepare an offer for a particular mobility order distributed by the consensus module at all and, in particular, with which parameters (price, scope, specification, etc.) to prepare the responding offer. In particular, the responding offer includes at least order fulfillment costs, expected order fulfillment times and/or expected order fulfillment durations. In addition, the responding offer may include other parameters that may be relevant in particular for a selection of a contract assignment, for example, an expected CO₂ footprint that will be generated when fulfilling the order, or a reputation of the originator of the responding offer (e.g. with regard to the adherence to the times promised in responding offers, with regard to the social compatibility of the working conditions of the company that owns the vehicle making the responding offer, etc.). In particular, in order to prepare an offer the decision module conducts an assessment of the incoming mobility orders by means of an offer preparation target function. The offer preparation target function may in particular include an operational cost function, a profit function and/or a benefit function. This offer preparation target function is used to calculate the costs (or user preferences) and hence also the prices and profitability (contribution margins, or preference values) of individual offer responses to the mobility order.

Furthermore, it is proposed that the separate decision module assigned to the terminal, in particular to each vehicle, preferably to each digital twin, is designed to prepare a mobility offer of the vehicle and to transmit the generated mobility offer to the decentralized consensus module for deployment as a smart contract within the distributed ledger technology (DLT), such as the directed acyclic graph (e.g. the IOTA tangle) or the blockchain. This means that a high level of efficiency, in particular optimum capacity utilization of the vehicle network, can be advantageously achieved. Every vehicle can advantageously report free mobility capacities independently and thus increase its capacity utilization. In particular, the mobility offer is prepared based at least on a current mobility capacity (transport capacity/service provision capacity), which is determined in particular by at least one sensor assigned to the vehicle, and/or based on current route planning, current itinerary planning and/or a current itinerary sequence, which is determined in particular by at least one navigation system assigned to the vehicle. In particular, the mobility offer is visible to and/or can be accepted by other vehicles in the network, drivers of other vehicles in the network and/or entities outside the network that have and/or report a requirement for freight transport, passenger transport or service provision.

To distinguish between the terms “route” and “itinerary”, the following is noted: a route determines how to get from A to B (e.g. Google Maps or other solutions). In contrast, an itinerary schedule also includes a sequence of stops for a vehicle. In the case of itinerary planning, additional constraints such as time windows and driving and rest times etc., increase the planning problem exponentially (which makes the problem already NP-complex and therefore only solvable with algorithms). Scheduling, orchestration and fleet or multi-vehicle itinerary planning, e.g. for a heterogeneous vehicle fleet with e.g. 50 different vehicles and 250 freight orders/stops with ancillary conditions such as payload, volume, time window, etc., increase the problem further by a very large factor. A further level of complexity is obtained by a dynamization of the scheduling, orchestration and fleet or multi- vehicle itinerary planning, which includes, for example, replanning events such as new ad hoc mobility orders after the itinerary has already started and/or spot markets for secondary freight with flexible times and locations for transshipment traffic.

If the decision module is designed for preparing the responding offer to the received mobility order or the mobility offer taking into account a free-area detection by a loading space sensor of the associated vehicle, which is in particular represented by the digital twin, a particularly efficient use of the transport capacity of vehicles of the network can be advantageously achieved. In particular, the responding offer to the received mobility order or the mobility offer includes a free area indication. In particular, the vehicle has a loading area monitoring device with a radar and/or LiDar sensor unit, as described in the filed but currently unpublished German patent application with the application number 10 2021 117 190.3. In particular, the loading space sensor is formed by this radar and/or LiDar sensor unit. The disclosure of the filed and currently unpublished German patent application with application number 10 2021 117 190.3 is herewith explicitly incorporated into the disclosure of this patent application. Alternatively or in addition, a sensor-based detection of a free volume by the loading space sensor can also be taken into account in preparing the responding offer.

Alternatively or additionally, if the decision module is designed for preparing the responding offer to the received mobility order or mobility offer taking into account a free-weight detection by a load weight sensor of the associated vehicle, in particular represented by the digital twin, a particularly efficient use of the transport capacity of vehicles of the network can be advantageously achieved. In particular, the responding offer to the received mobility order or the mobility offer includes a free weight indication. In particular, the vehicle has a weighing system which is designed to determine a load weight. For example, the load weight sensor may be designed as a weighing system integrated in an axle of the vehicle.

If, alternatively or in addition, the decision module is designed to prepare the responding offer to the received mobility order, in particular together with a mobility order assessment prepared by the decision module, or to prepare the mobility offer taking into account geolocation data, taking into account an operational cost function of the vehicle including pre-cost centers and overheads, taking into account a target profit and/or taking into account a current itinerary sequence, preferably a route schedule, a current itinerary schedule and/or a current itinerary sequence of a navigation system of the associated vehicle, in particular represented by the digital twin, in particular if other mobility orders have already been assigned to the vehicle, a particularly efficient utilization of vehicles in the network can be advantageously achieved. Advantageously, particularly efficient vehicle routes can be planned for the vehicles in the network. This can advantageously achieve energy savings and/or a reduction in CO₂ emissions. The geolocation data is preferably composed of original and/or current geographical coordinates of the vehicle, from the geographical coordinates of already accepted mobility orders, in particular collection and delivery locations of already accepted mobility orders (and/or mobility offers), and/or from the geographical coordinates of transfer locations at which goods or persons are handed over to other vehicles of the network. If a predeterminable detour threshold is exceeded, no responding offer is prepared. Other factors that can be considered alternatively or additionally in the preparation of the respective responding offer to the received mobility order are a vehicle-specific operational cost function, a temporal limitation of the vehicles and/or the destination locations and/or the driving personnel and/or the permitted implementation times. If hard secondary conditions are violated, such as driving and rest times, free cargo space, available payload or other predefined parameters, such as expected costs, profit, etc., a responding offer is preferably not prepared.

Furthermore, it is proposed that the terminal forms at least part of an integrated vehicle-computer unit of the vehicle, for example a vehicle on-board computer, a vehicle control unit/vehicle microcontroller, a built-in vehicle navigation device or the like, or at least part of a mobile computer that can be assigned to the vehicle, for example an external navigation device, a smartphone, mini-computer or tablet of the vehicle driver, a hand scanner of the driver, or the like. This can advantageously ensure a secure assignment between the terminal and the vehicle of the network.

In addition, it is proposed that the consensus module is designed to select, in particular independently, at least one best offer from all received responding offers and to transmit a contract confirmation for the mobility order back to the vehicle with the selected responding offer. This allows a high level of efficiency, in particular control efficiency of the vehicle network, to be advantageously achieved. In particular, the consensus module for selecting the best offer performs an assessment of each responding offer received from different vehicles by means of a contract target function. The contract target function may in particular include an operational cost function, a profit function and/or a benefit function. For example, the responding offer that maximizes/minimizes the contract target function of the consensus module will then receive the contract confirmation.

Durations of mobility orders, in particular the smart contracts, can vary in length, with the end of the term being made known to all participants of the decentralized control system to which the smart contracts are transmitted. The smart contracts can therefore be active for different lengths of time. In particular, the smart contracts and thus the mobility orders are active for a defined and visible time period, wherein responding offers to the mobility orders can be submitted until the time period expires. After the end of the period, the offer phase closes and regulation is carried out by executing the smart contract with pricing and awarding of the contract. The determination of the contract price can take place with an open price negotiation (e.g. in the case of smart contracts of the first category) or with a hidden price negotiation (in the case of smart contracts of the second category).

It is also proposed that the decentralized control system has a serverless infrastructure. This can advantageously ensure a high level of security, in particular against hacker attacks, and/or a cost-effective and reliable functioning.

Furthermore, it is proposed that the consensus module is distributed in a decentralized form over a plurality of terminals assigned to different vehicles, in particular integrated vehicle-computer units and/or mobile computers that can be assigned to the vehicles. This can advantageously ensure a high level of security, in particular against hacker attacks, and/or a cost-effective and reliable functioning. In particular, the consensus module is designed as an operating program, which is pre-installed and/or retrofitted in a distributed manner over a plurality of terminals assigned to the different vehicles. In particular, the consensus module comprises the digital ledger of the DLT. In particular, the digital ledger of the DLT is distributed over the plurality of terminals assigned to different vehicles. Alternatively, however, it is also conceivable that the consensus module and/or the digital ledger of the DLT is operated separately from the terminals of the vehicles, for example stored (in a decentralized manner) on the Internet.

In particular, the consensus module may be designed to find different types of consensus: i) Consensus between vehicles of collaborating and competing fleets to form a vehicle platoon and/or under what conditions to form it and/or in what order the vehicles should drive in the platoon and/or how the cost savings of a platoon are to be distributed among the individual platoon participants. ii.) Consensus among vehicles and/or between vehicles and computer systems in order to coordinate the allocation of trailers/attachments/containers/freight capsules/passenger capsules etc.; which vehicle is to receive which trailer/attachment/container etc. at what time and which locations and exchange them in transshipment traffic. Both collaborating and competing vehicles can participate. iii.) Consensus among vehicles and/or between vehicles and computer systems to manage and schedule the loading ramps and/or loading ramp allocations and/or loading platforms and/or transshipment platforms and/or loading or transshipment hubs. For example, a consensus can be reached on which vehicle may occupy which loading ramp, when and for how long. iv.) Consensus among vehicles and/or between vehicles and computer systems on traffic control and traffic light phases, on a passage along e.g. a traffic light-controlled road and/or traffic light-controlled route section and/or air route and/or ship passage, which vehicle has to wait when and for how long or may/should pass through/fly through and be shown a green light and under what conditions. v.) Consensus among vehicles and/or between vehicles and intralogistics loading robots and/or forklifts, which, e.g., robot should load and unload which vehicle, when and where. vi.) Consensus among vehicles and/or between vehicles and driving crew scheduling systems in order to coordinate the deployment of the driving crew. Which driver drives which vehicle, where and when. vii.) Consensus among vehicles and/or between vehicles and loading device management systems (e.g. pallets) on the charging and settlement of available and/or deployed loading devices. viii.) Consensus among vehicles and/or between vehicles and a computer system to share individually and vehicle-specific learned information and evaluations (e.g. from sensors on average loading, or optimal clustering, or algorithm improvements) with other collaborating and competing vehicles and under what conditions to share them.

If at least some of the terminals form distributed ledger technology (DLT) nodes, a high level of security can be advantageously achieved. In particular, the consensus module is operated in a distributed manner among at least some of the terminals of the vehicles of the network, preferably among all terminals of the vehicles of the network, as DLT nodes.

Furthermore, an in particular computer-implemented, decentralized control method for the intra-fleet and/or inter-fleet, at least partially self-organized, control of a network formed at least by vehicles, in particular by passenger transport vehicles, goods transport and/or service vehicles is proposed, in particular having a decentralized control system, wherein in at least one method step, mobility orders, in particular network-external or network-internal transport orders or service provision orders, and/or mobility offers, in particular internal transport offers or service provision offers, of vehicles of the network, in the form of smart contracts within a distributed ledger technology (DLT), such as a directed acyclic graph (e.g. an IOTA tangle) or a blockchain, are transmitted to more than one terminal, the terminals being assigned in each case to vehicles of the network. This allows a high efficiency, in particular control efficiency of the vehicle network, to be advantageously achieved. Optimum utilization of the vehicles of the network can be advantageously achieved.

In addition, it is proposed that in at least one method step, by at least one terminal which is assigned to an individual vehicle of the network a mobility offer is prepared and is transmitted to the decentralized consensus module for deployment as a smart contract within the distributed ledger technology (DLT). This means that a high level of efficiency, in particular optimum capacity utilization of the vehicle network, can be advantageously achieved. Every vehicle can advantageously report free mobility capacities independently and thus increase its capacity utilization.

In addition, it is proposed that in at least one method step, by at least one further terminal, in particular one which is different from the terminals assigned to the vehicles of the network devices and/or network-external, a mobility order is prepared and is transmitted to the decentralized consensus module for deployment as a smart contract within the distributed ledger technology (DLT). This can advantageously allow a simple form of order preparation.

If, in at least one method step, by terminals which are in each case assigned to individual vehicles of the network, it is decided, based on an individual evaluation of an offer preparation target function for the respective assigned vehicle, whether (and at what price and/or at what minimum price) a responding offer to the mobility order will be submitted, a high level of efficiency of the decentralized control method can be advantageously achieved.

If in at least one further method step the respective terminal then prepares a responding offer to the mobility order, an autonomous organization of the control method can advantageously be achieved.

Furthermore, it is proposed that for an evaluation of the offer preparation target function, for preparing the responding offer and/or for preparing the mobility offer, the following information is considered: an available free area/free volume/capacity of the vehicle, an available free weight of the vehicle, a temporal availability of the vehicle, an already planned route, an already planned itinerary, an already begun itinerary, an already planned itinerary sequence, an already begun itinerary sequence and/or a planned itinerary and/or itinerary sequence of the vehicle combined from new mobility orders and/or geolocation data of the vehicle and/or the start and/or destination locations of the mobility order, permitted driving and rest periods of the driving crew, currently remaining driving and rest periods of the driving crew, an operational cost function of the driving crew, including relevant pre-cost centers and overhead cost allocations, possible pause geolocations for rest periods of the driving crew, an operational cost function of the vehicle including relevant pre-cost centers and overhead cost allocations, and/or target profit specifications (e.g. per distance unit, per time unit, per payload unit, per volume unit or a flat-rate target profit specification). This can advantageously achieve a particularly efficient utilization of transport capacities of vehicles in the network. In addition, this advantageously allows a simple pricing (consensus) to be found for the mobility order. The target profit specifications can be variable or fixed, e.g. 15% over costs, €50 per pallet, €5 per ton-kilometer or a flat-rate €50 per order. Machine learning can be used to determine the target profit specification.

It is also proposed that, in at least one further method step, all responding offers submitted by terminals assigned to different vehicles are evaluated by means of a contract target function of the smart contract, wherein at least one best offer is determined according to the criteria of the contract target function and wherein the contract is awarded at least to the vehicle having the terminal from which the best offer originates. This allows a high efficiency, in particular control efficiency of the vehicle network, to be advantageously achieved. In particular, to determine the best offer, a price, a duration, a time of arrival, a collection time, an environmental parameter, a social parameter or preferably a combination of the above, is optimized. For example, the best offer can be based on a shortest duration, lowest price, most accurate arrival date, earliest collection time, most accurate collection time, a lowest fuel consumption and/or a smallest CO₂ footprint. It is conceivable that within a fleet, coordination takes place between vehicles belonging to the fleet before a responding offer of a vehicle belonging to the fleet is prepared. This can advantageously prevent vehicles of an operator/fleet from competing with each other. The proposed combination of continuous decision-making using the collaboration of the decision-making module and consensus module creates a form of distributed artificial intelligence with a completely serverless infrastructure.

In addition, it is proposed that a combination of submitted responding offers is determined as the best offer and the contract is awarded to more than one vehicle. This can advantageously achieve optimum utilization efficiency of network vehicles. For example, in such a case, one part of a mobility order (e.g. the transport of 3 of 5 pallets from X to Y) can be awarded to a first vehicle A of the network, while a further part of the mobility order (e.g. the transport of the remaining 2 of 5 pallets from X to Y) is awarded to a second vehicle B of the network. Accordingly, a responding offer to an open mobility order may only relate to one part of the mobility order, in particular if a vehicle only has a limited transport capacity available.

If, in at least one method step, the mobility order is integrated into an updated route guidance in an automated manner, an updated itinerary sequence and/or an updated itinerary schedule, in particular of a navigation device, of the vehicle or vehicles receiving the contract, high efficiency can be advantageously achieved. In addition, errors (e.g. an oversight of an assigned order) can be advantageously avoided. Alternatively, however, it is also conceivable that the updated route guidance, itinerary sequence and/or itinerary schedule must be manually imported into a navigation device of the vehicle.

If the decentralized control method enables that in at least one method step, a mobility order for which a vehicle has already been awarded the contract is forwarded from the terminal of the vehicle as a secondary mobility order, a high level of flexibility can advantageously be achieved.

In this case, it is proposed that the secondary mobility order, in the form of a smart contract within the distributed ledger technology (DLT), such as a directed acyclic graph (e.g. an IOTA tangle) or a blockchain, is transmitted to terminals of more than one vehicle of the network. This advantageously allows a straightforward assignment of the secondary mobility contracts. In particular, the procedure for issuing secondary mobility orders is essentially identical to the procedure for awarding mobility orders (with the difference that the secondary mobility orders originate from vehicles in the network, whereas mobility orders usually come from external clients).

It is also proposed that the secondary mobility order be offered in a spot market for secondary mobility contracts. This allows a high degree of flexibility to be advantageously achieved. Secondary mobility orders are, in particular, remotely comparable to a secondary market for securities. A trigger for a secondary mobility order may be, for example, that an itinerary composition of a vehicle has changed (traffic congestion, unplanned stops, further orders, etc.), that more vehicles have been added to the network and/or that more profitable orders are available for a vehicle.

The decentralized control system according to the invention and the decentralized control method according to the invention shall not be restricted to the application and embodiment described above. In particular, in order to fulfil a function described herein the decentralized control system according to the invention and the decentralized control method according to the invention may have a number of individual elements, components and units that differs from a number specified herein.

### DRAWINGS

Further advantages are obtained from the following description of the drawings. The drawings illustrate an exemplary embodiment of the invention. The drawings, the description and the claims contain numerous features in combination. The person skilled in the art will also advantageously consider the features individually and combine them to form further meaningful combinations.

In the drawings:

FIG. 1 shows a schematic representation of a network of vehicles with a decentralized control system,

FIG. 2 shows a schematic representation of the decentralized control system,

FIG. 3 shows a schematic representation of a vehicle in the network and

FIG. 4 shows a schematic flow diagram for a decentralized control method.

### DESCRIPTION OF THE EXEMPLARY EMBODIMENT

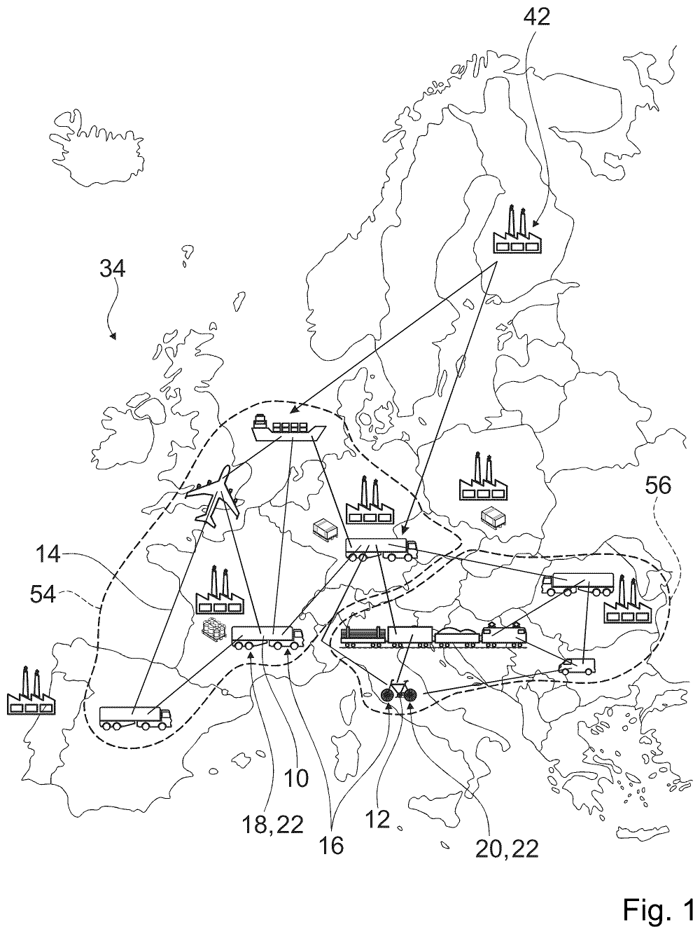

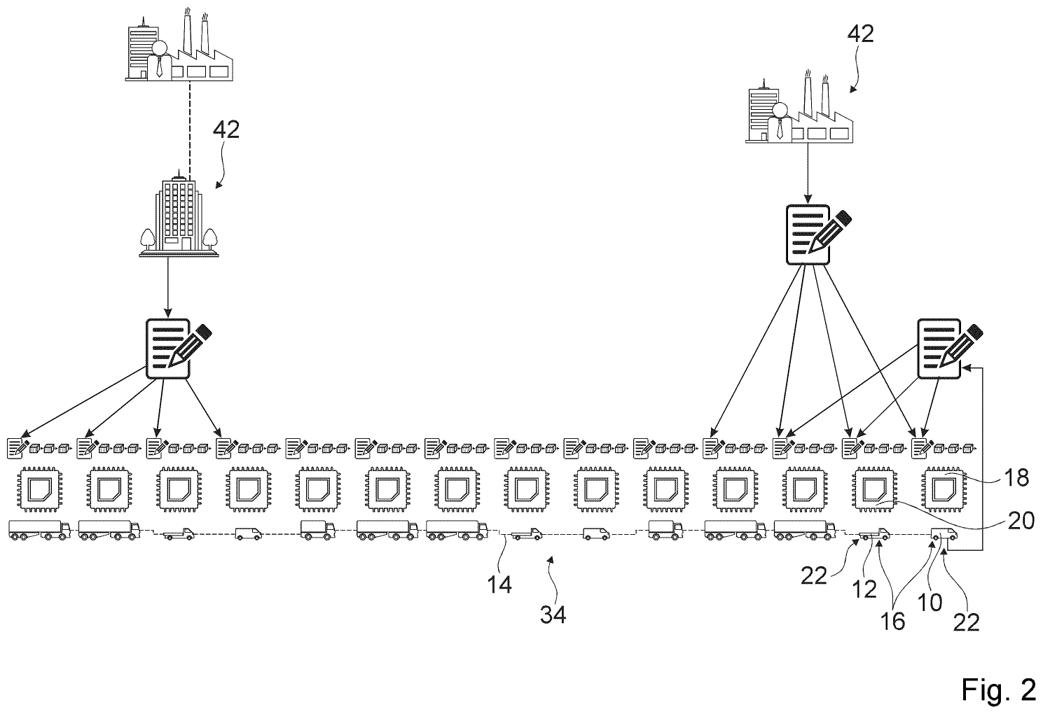

FIG. 1 shows a schematic drawing of a decentralized control system 34. The decentralized control system 34 is designed for the intra-fleet and/or inter-fleet control of a network 14 formed by vehicles 10, 12. The decentralized control system 34 is designed for the self-organized control of the network 14 formed by the vehicles 10, 12. The network 14 comprises a multiplicity of vehicles 10, 12. By way of example, the vehicles 10, 12 are shown predominantly as road vehicles. However, at least some of the vehicles 10, 12 could also be formed by other non-road vehicles. By way of example, the vehicles 10, 12 are shown as transport vehicles. Alternatively, however, at least some of the vehicles 10, 12 could be in the form of service vehicles. The vehicles 10, 12 are assigned, for example, to two fleets 54, 56. Of course, the network 14 can also comprise more or fewer than two fleets 54, 56. As an example, at least some of the vehicles 10, 12 are currently carrying out a transport order and following a currently specified route between the loading location and the unloading location. Each vehicle 10, 12 is assigned a terminal 18, 20. The terminal 18, 20 in the exemplary case illustrated forms at least part of an integrated vehicle-computer unit 30 of the vehicle 10, 12. The terminal 18, 20 in the exemplary illustrated case (see FIG. 2) is designed as an on-board unit. The terminal 18, 20 in the exemplary case illustrated (see FIG. 2) is designed as a control unit of the vehicle 10, 12. Alternative embodiments (not shown), relating to the vehicle 10, 12, and embodiments (also not shown) as mobile computers, which are assigned to the vehicle 10, 12, preferably a driver of the respective vehicle 10, 12, are also conceivable.

The decentralized control system 34 forms a (central) serverless infrastructure. Each vehicle 10, 12 of the network 14 is represented in the decentralized control system 34 by a digital twin. Each of the digital twins in the decentralized control system 34 forms an agent of a multi-agent system, which is able to take autonomous decisions concerning the assigned vehicle 10, 12. The multi-agent system is thus formed by the totality of the digital twins representing the vehicles 10, 12 of the network 14 and their interaction/communication with each other.

The decentralized control system 34 forms a decentralized consensus module 16. The consensus module 16 is distributed among a plurality of terminals 18, 20, assigned to different, preferably all vehicles 10, 12 of the network 14, such as the integrated vehicle-computer units 30 and/or the mobile computers assigned to the vehicles 10, 12, in a decentralized architecture. The decentralized control system 34 is based on a distributed ledger technology (DLT), preferably on a DLT organized by directed acyclic graphs, such as the IOTA communication protocol. Alternatively, simply concatenated lists, such as blockchains, are also conceivable. All transactions within the decentralized control system 34 are entered (in tamper-proof and traceable form) in a distributed ledger of the DLT. At least some of the terminals 18, 20 of the decentralized control system 34, preferably all terminals 18, 20 of the decentralized control system 34, form distributed ledger technology (DLT) nodes.

The decentralized consensus module 16 is designed to transmit mobility orders in the form of smart contracts within the distributed ledger technology (DLT) to a plurality of the terminals 18, 20 of vehicles 10, 12 of the network 14, preferably to all active terminals 18, 20 of vehicles 10, 12 of the network 14. The mobility orders can be transport orders or service provision orders, which are commissioned by network-external entities, e.g. logistics brokers, product manufacturers or the parent company of the vehicles via a TMS, ERP or WAWI, distance traders, online dealers, etc. or by network-internal entities, e.g. the vehicles 10, 12. The decentralized consensus module 16 is designed to transmit mobility offers in the form of smart contracts within the distributed ledger technology (DLT) to a plurality of the terminals 18, 20 of vehicles 10, 12 of the network 14, preferably to all active terminals 18, 20 of vehicles 10, 12 of the network 14. The mobility offers can be transport offers or service provision offers, which are offered by the vehicles 10, 12 of the network 14.

The decentralized control system 34 comprises decision modules 22. Each vehicle 10, 12 is assigned a separate decision module 22. The decision module 22 of a vehicle 10, 12 is installed on a terminal 18, 20 of the vehicle 10, 12 in each case. The decision module 22 can be formed by the same terminal 18, 20 on which the consensus module 16 also runs. Each of the terminals 18, 20, in particular each vehicle 10, 12, preferably each digital twin of the decentralized control system 34 is assigned precisely one separate decision module 22. The decision module 22 is designed to receive the mobility offer and/or the mobility order. The decision module 22 is designed to analyze the smart contract. The decision module 22 of a vehicle 10, 12 is designed for preparing a responding offer assigned to the vehicle 10, 12 at least to received mobility orders.

The decision module 22 is designed to prepare a mobility offer of the vehicle 10, 12. The mobility offer includes an offer from the vehicle 10, 12 to accept a transport order at a certain time between certain locations, or an offer to perform a service at a certain time at a certain location. The decision module 22 is designed to transmit the prepared mobility offer to the decentralized consensus module 16 for deployment as a smart contract within the distributed ledger technology (DLT). The consensus module 16 is designed to select at least one best offer from all received responding offers and to transmit a contract confirmation for the mobility order back to the vehicle 10, 12 with the selected responding offer. The decision module 22 of the vehicle 10, 12 is designed to accept the contract confirmation. The decision module 22 of the vehicle 10, 12 is designed to integrate the mobility order into a route guidance, itinerary sequence, itinerary schedule and/or into a time schedule of the vehicle 10, 12. The vehicle 10, 12 which receives the contract confirmation then carries out the mobility order. It is conceivable that the vehicle 10, 12 is designed as an autonomously driven vehicle, which follows the route guidance modifiable by the decision module 22. The decentralized control system 34 is thus designed to assume control of the vehicles 10, 12 of the network 14 via the consensus module 16.

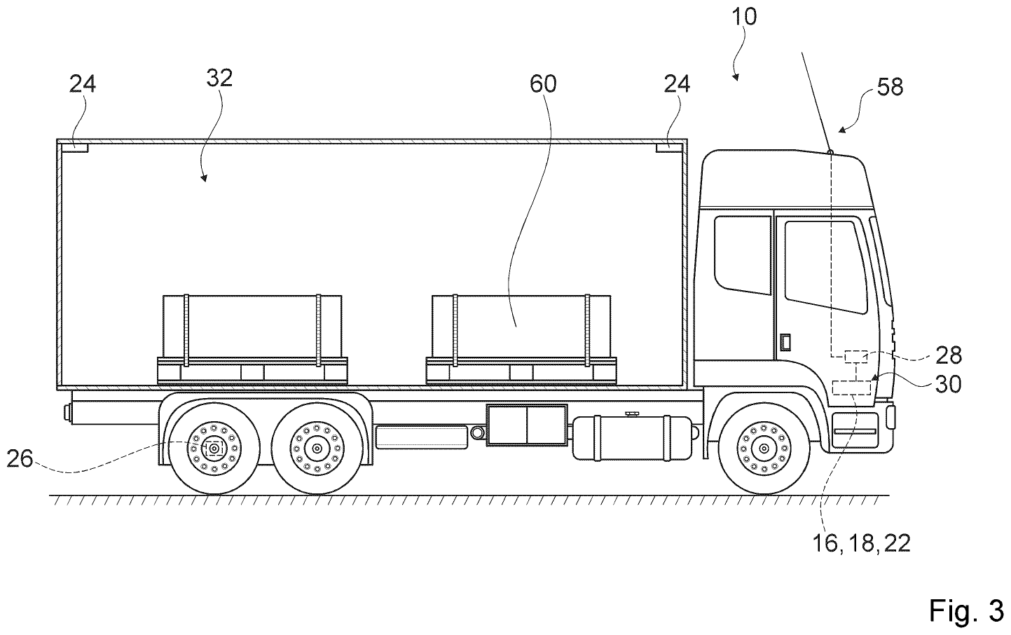

FIG. 3 shows an exemplary vehicle 10 of the network 14. The vehicle 10 is designed as a heavy goods vehicle. The vehicle 10 comprises the vehicle-computer unit 30, which partially comprises the consensus module 16 and completely comprises the decision module 22. Alternatively, it is also conceivable that parts of the decision module 22, e.g. map material or an address service, are outsourced to a cloud or the like. The vehicle 10 has a navigation system 28. The navigation system 28 communicates with the decision module 22 of the vehicle 10. The vehicle 10 has a communication system 58. The communication system 58 is designed for communication with other vehicles 12 of the network 14. The communication system 58 is designed for communication between the parts of the consensus module 16 assigned to the various vehicles 10, 12. The communication system 58 is designed to receive the mobility orders and/or the contract confirmations. The communication system 58 is designed for sending responding offers and/or mobility orders.

The vehicle 10 has a loading space 32. In the example case shown, the loading compartment 32 is designed for the transport of goods 60. The vehicle 10 comprises at least one loading space sensor 24. The loading space sensor 24 is designed to monitor the loading space 32. The loading space sensor 24 corresponds to the loading space sensor 24 described in the previously unpublished, filed German patent application with application number 10 2021 117 190.3 and referred to there as a monitoring sensor. The loading space sensor 24 is designed as an ultra-wideband radar sensor. Alternatively, the loading space sensor 24 can also be based on another sensing method, e.g. on an optical camera. The loading space sensor 24 is designed for free-area detection. The loading space sensor 24 is designed to detect unused regions of the loading space 32 that are still available for loading. The decision module 22 is designed to provide the responding offer to the received mobility order or to the received mobility offer, taking into account the free-area detection of the loading space sensor 24 of the vehicle 10, represented in particular by a digital twin in the decentralized control system 34. The vehicle unit 10 has a load weight sensor 26. The load weight sensor 26 is designed to measure the load weight on an axle of the vehicle 10. The load weight sensor 26 is designed to detect a total weight of goods 60 loaded in the loading space 32. The load weight sensor 26 is designed to determine a free weight of the vehicle 10. The loading space sensor 24 is designed to allow determination of a payload of the vehicle 10 still available for loading. The decision module 22 is designed to prepare the responding offer to the received mobility order or to the received mobility offer, taking into account the free-weight detection of the load weight sensor 26 of the vehicle 10, which is represented in particular by a digital twin in the decentralized control system 34.

The decision module 22 is linked to the navigation system 28. The decision module 22 is designed to retrieve a current route schedule and/or itinerary schedule and/or itinerary sequence from the navigation system 28. The decision module 22 is designed to retrieve geolocation data from the navigation system 28. The decision module 22 is designed to provide the responding offer to the received mobility order or to the received mobility offer taking into account the geolocation data and/or taking into account the current route schedule (current itinerary schedule, current itinerary sequence) of the navigation system 28 of the vehicle 10, which is in particular represented by the digital twin in the decentralized control system 34. The decision module 22 is designed to retrieve cost data from a computer system (from a fleet management system or from an inventory management system, an enterprise resource planning system and/or a transport management system or the like). The decision module 22 is designed to derive cost data as a vehicle-specific operational cost function. The decision module 22 is designed to retrieve target profit specifications from the computer system. The decision module 22 is designed to retrieve live traffic data from a computer system (e.g. an on-board system, in particular a navigation system, or via the Internet). The decision module 22 is designed to retrieve address data from a computer system. The decision module 22 is designed to resolve address data in geolocations. The decision module 22 is designed to calculate and derive a vehicle-specific offer preparation target function from all the data obtained. The decision module 22 can use artificial intelligence, in particular neural networks and/or machine learning, for each of the data items and/or for each combination of the data, in order to generate a prediction for extrapolation of the data. The decision module 22 can use artificial intelligence, in particular neural networks and/or machine learning, for the preparation of the offer preparation target function.

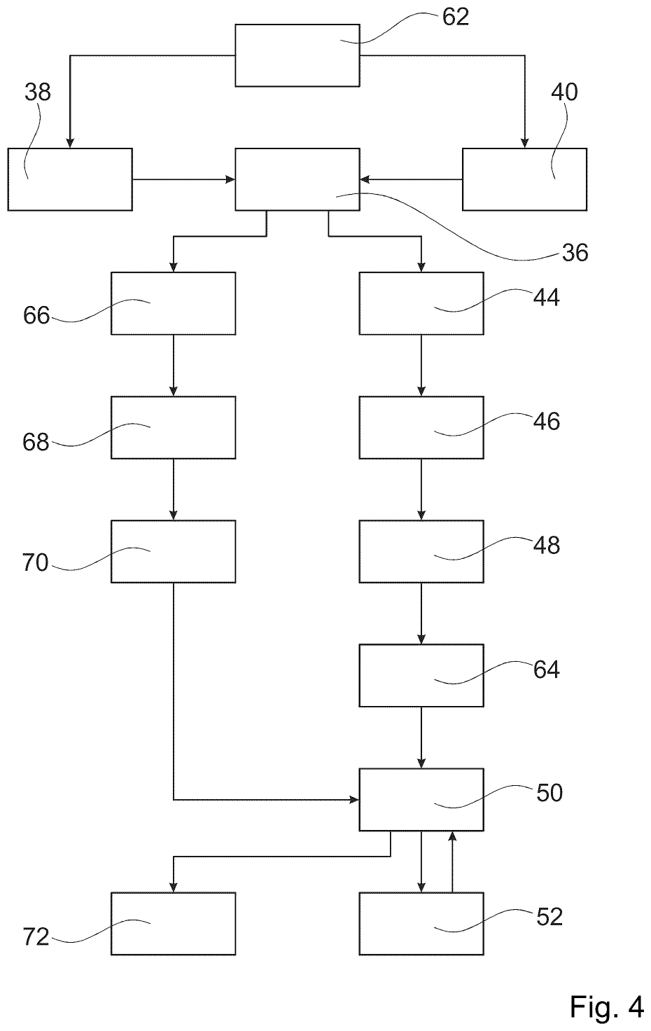

FIG. 4 shows a schematic flow diagram of a decentralized control method for an intra-fleet or inter-fleet, self-organized control of the network 14 formed by the vehicles 10, 12. In at least one method step 62, a consensus module 16 distributed in a decentralized manner over the vehicles 10, 12 of the network 14 is provided.

In at least one method step 40, a further terminal 42, which is different from the terminals 18, 20 assigned to the vehicles 10, 12 of the network 14 and is not assigned to any of the vehicles 10, 12 of the network 14 (e.g. a computer system of a logistics broker, a computer system of a parent company for collaborating fleets, such as the fleet management system or the inventory control system, the enterprise resource planning system and/or the transport management system), prepares a mobility order and submits it to the decentralized consensus module 16 for deployment as a smart contract within the DLT. In at least one method step 36, the mobility orders received by the consensus module 16 in the form of smart contracts within the DLT are transmitted to more than one terminal 18, 20. The mobility orders come either from external contracting entities that want to make use of the capacities of the network 14, or else from internal contracting entities that want to broker or relocate orders within the network 14. In at least one method step 44, the terminals 18, 20, which are each assigned to the individual vehicles 10, 12 of the network 14, decide based on an individual evaluation of an offer preparation target function for the respective assigned vehicle 10, 12 whether, and in particular with which parameters (price, scope, specification), to submit a responding offer to the mobility order. Each vehicle 10, 12 can possess/define a separate offer preparation target function. In method step 44, for an evaluation of the offer preparation target function and/or for preparing the responding offer, the following information is taken into account: an available free area of the vehicle 10, 12, an available free volume of the vehicle 10, 12, an available capacity of the vehicle 10, 12, an available free weight of the vehicle 10, 12, a temporal availability of the vehicle 10, 12, an already planned route, an already planned itinerary schedule, a planned itinerary sequence, already begun routes, an already begun itinerary and/or an already begun itinerary sequence of the vehicle 10, 12, geolocation data of the vehicle 10, 12 and/or possible transshipment points, the desired starting point of the mobility order, the desired destination of the mobility order, a vehicle-specific operational cost function, relevant operational pre-cost centers, operational overheads, in particular costs of the driving crew, live traffic data, historical traffic data, driving and rest times of the driving crew, remaining driving and rest times of the driving crew, possible break and rest places of the driving crew, refueling stops, topographical road conditions, opening times of a mobility order geolocation, agreed ramp times of the collection and delivery locations, waiting times within a mobility order, a maximum allowed execution time of a mobility order, and/or target profit specifications. The decision module 22 can use artificial intelligence, in particular neural networks and/or machine learning, for the preparation of the responding offer. In at least one further method step 46, the responding offer is prepared by the respective terminal 18, 20 which has decided on the basis of the offer preparation target function to submit a responding offer to the mobility order. The responding offer includes possible locations, possible times, price requirements and available capacities for the fulfillment of the mobility order. In at least one further method step 48, all responding offers submitted by terminals 18, 20 assigned to different vehicles 10, 12 are evaluated by means of a contract target function of the smart contract forming the mobility order. In method step 48, a best offer is determined according to the criteria of this contract target function. In at least one further method step 64, the contract is awarded to the vehicle 10, 12 having the terminal 18, 20 from which the best offer originates. In the method step 64, the confirmation of the contract is transmitted to the vehicle 10, 12, having the terminal 18, 20 from which the best offer originates. It is also conceivable that in method step 64 a combination of submitted responding offers will be determined as the best offer and the contract will be divided over more than one vehicle 10, 12. In at least one method step 50, the mobility order is integrated into an updated route guidance in an automated manner, itinerary sequence and/or itinerary schedule of the vehicle/vehicles 10, 12 which has/have obtained the contract.

Alternatively or additionally, in method step 36, mobility offers in the form of smart contracts within the DLT can also be transmitted to more than one terminal 18, 20. For this purpose, in a method step 38 preceding the method step 36, one of the terminals 18, 20, which is assigned to one of the vehicles 10, 12 of the network 14, prepares a mobility offer and transmits it to the decentralized consensus module 16 for deployment as a smart contract within the DLT. The mobility offer prepared by the vehicle 10, 12 includes at least regions, times and capacities, which are made available by the vehicle 10, 12. In method step 36, the mobility offers received by the consensus module 16 are then transmitted to more than one terminal 18, 20 in the form of smart contracts within the DLT. The mobility offers therefore originate from the vehicles 10, 12 or the fleets 54, 56 of the network 14 itself and represent offers to external contracting entities. In preparing the mobility offer, an available free area of the vehicle 10, 12, an available free volume of the vehicle 10, 12, an available capacity of the vehicle 10, 12, an available free weight of the vehicle 10, 12, a temporal availability of the vehicle 10, 12, an already planned route, an already begun route, a planned itinerary, an already begun itinerary and/or an already begun itinerary sequence of the vehicle 10, 12, geolocation data of the vehicle 10, 12, the desired starting point of the mobility order and/or the desired destination of the mobility order are taken into account. This provides the recipient of the mobility offer with precise information about the transport capacities. In at least one further method step 66, one or more recipients of the mobility offer prepare response orders to the mobility offer. These response orders include accurate details of desired locations, times, capacities and a price proposal. The desired locations, times, capacities and price proposal may differ from the locations, times, capacities and price requests offered. In at least one method step 68, all response orders are evaluated by means of a contract target function of the smart contract forming the mobility offer. In method step 68, a best order is determined according to the criteria of this contract target function. In at least one further method step 70, the contract is awarded to the external contracting entity from which the best order originates. Here, too, it is conceivable that in method step 70 a combination of submitted response orders will be determined as the best order and the contract will be split between more than one external contracting entity. In method step 50, the order which has obtained the contract for the mobility offer is integrated into an updated route guidance, an updated itinerary sequence and/or an updated itinerary schedule of the vehicle making the mobility offer 10, 12.

In at least one method step 52, a mobility order for which a vehicle 10, 12 has been awarded the contract, is forwarded by the terminal 18, 20 of the vehicle 10, 12 as a secondary mobility order. The secondary mobility order is transmitted in the form of a smart contract within the DLT to the terminals 18, 20 of the vehicles 10, 12 of the network 14. The secondary mobility order is subsequently treated as a mobility order. The secondary mobility order can be adjusted before or after execution begins. The secondary mobility order may include fixed or flexible times, and/or flexible or fixed locations for the transshipment traffic. The decision module 22 of the vehicle 10, from which the secondary mobility order originates, negotiates with further decision modules 22 of other vehicles 12 over a flexible time and/or a fixed time and/or a flexible location and/or a fixed location for carrying out the transshipment traffic for the transshipment of the relevant transport entities (passengers, freight, etc.).

Alternatively or in addition, it is conceivable that the secondary mobility order is offered in a spot market for secondary mobility orders, to which not only the subscribers to the network 14 have access, but also other parties/vehicles 10, 12 that are not participating in the network 14.

In at least one further method step 72, the mobility order or the secondary mobility order is executed by the vehicle 10, 12 that has been awarded the contract.

In the decentralized control method it is determined, in particular in method step 44, whether a goods transport is profitable. This takes into account all available data, such as employees, vehicle costs, consumption, pre-cost centers, overhead charges, geolocation of the vehicle 10, planned and begun itinerary sequence, implicit costs, insurance costs, topographical road data, live traffic data, driving and resting times, waiting times, free loading space, available payload, etc. The decision module 22 then dynamically calculates whether mobility orders are profitable, at what price mobility orders would be profitable, and/or whether mobility orders are feasible in terms of time/capacity. If it turns out during the journey that delays occur for a certain mobility order, e.g. for a certain general cargo, and as a result higher costs are incurred than planned or that agreed conditions for a certain mobility order, e.g. for a certain general cargo, cannot be met, the vehicle 10 can attempt to offload the mobility order, for example, to another vehicle 12 which may be driving to the destination anyway and/or for which this transport order is profitable.

The following example is intended to illustrate this method. For example, a parcel service provider still has 3 parcels to deliver, which, however, must be driven to a remote district on the outskirts of a city. The vehicle 10, 12/the decision module 22 now calculates that a delivery of these three parcels will take 28 minutes and cost €23, but at the same time the parcel service provider receives only €21 for the delivery. The delivery of the parcels would therefore incur a loss. The parcel service provider can now send a secondary mobility order for the three packages as a mobility order to the network 14 or place it on the spot market for secondary mobility orders as a secondary mobility order. In this case the parcel service provider can define a maximum valid price, e.g. 23 EUR as a break-even price. For example, a bicycle courier then discovers the secondary mobility order on the spot market. Alternatively or in addition, a terminal (smartphone) assigned to the bicycle courier receives the mobility order. The bicycle courier, who as it happens is traveling this route anyway and who still has time before he has to return to his contractor who is located in the same direction, then makes an offer on the secondary mobility order or the mobility order. For example: Acceptance of the order for: minimum €15, Transfer location: Central Station or City Hall. The consensus module derives a consensus between the mobility order and the responding offer (supply and demand), taking into account responding offers from other network subscribers, and determines a mutually binding consensus value (price in this case). If the bicycle courier is then awarded the contract, the three packages will be handed over to him at an agreed geo-position. The handover of the packages and the agreed conditions are recorded in the digital ledger of the DLT. In addition, payments can also be processed immediately via the DLT, for example in a cryptocurrency linked to the DLT, such as MIOTA. It is also conceivable that a reputation module, which assigns a reputation to subscribers in the decentralized control method, can be used to create trust between transport companies that are not known to each other. The reputation of the parties can also be incorporated into the decision on the submission of offers by the decision module 22 or the awarding of contracts by the consensus module 16. All transactions, including payments, take place via smart contracts in the DLT. In the above example, only the scanning of the packages, the handover at the proposed geo-positions and the delivery to the destination are performed by human beings. The individual participants in the decentralized control method, i.e. the individual agents of the multi-agent system, conclude the contracts with each other independently without an intermediary. Network-external contracting entities can also act as agents in the multi-agent system.

In another example, instead of the bicycle courier, an independent carrier could respond to the secondary mobility order. To this end, a decision module 22 of the independent carrier imports the secondary mobility order in an automated manner, for example, from the consensus module 16. Via sensors 24, 26 the decision module 22 determines in advance or during the decision-making process whether/that free loading space space and/or payload is still available. After the calculation of the decision module 22 of the independent carrier (e.g. on-board unit or smartphone), taking into account all relevant parameters, in particular costs, the decision module 22 evaluates the secondary mobility order. For example, if the independent carrier's vehicle 10 is on a return trip and is looking for a reload, a prohibitive price will be calculated. For example, a minimum of €15.

### REFERENCE SIGNS

10 vehicle
12 vehicle
14 network
16 consensus module
18 terminal
20 terminal
22 decision module
24 loading space sensor
26 load weight sensor
28 navigation system
30 vehicle-computer unit
32 loading space
34 control system
36 method step
38 method step
40 method step
42 additional terminal
44 method step
46 method step
48 method step
50 method step
52 method step
54 fleet
56 fleet
58 communication system
60 goods
62-72 method step

1. A decentralized control system for the intra-fleet and/or inter-fleet, at least partially self-organized, control of a network (14) formed at least by vehicles, comprising a decentralized consensus module, which is designed for transmitting mobility orders, in particular network-external or network-internal transport orders or service provision orders, and/or mobility offers, in particular transport offers or service provision offers of vehicles of the network, in each case in the form of smart contracts within a distributed ledger technology, such as a directed acyclic graph (e.g. an IOTA tangle) or a blockchain, to more than one terminal, the terminals being respectively assigned to vehicles of the network.

2. The decentralized control system as claimed in claim 1, wherein each vehicle of the network is represented by a digital twin.

3. The decentralized control system as claimed in claim 2, wherein each digital twin is an autonomous decision-making agent in a multi-agent system, wherein the multi-agent system is formed at least by the totality of the digital twins each representing vehicles of the network and of their interaction/communication with each other.

4. The decentralized control system as claimed in claim 1, wherein each terminal, in particular each vehicle, preferably each digital twin, is assigned a separate decision module, which is designed to prepare at least one responding offer assignable to the vehicle in response to at least one received mobility order and preferably to transmit said responding offer to the consensus module.

5. The decentralized control system as claimed in claim 1, wherein each terminal, in particular each vehicle, preferably each digital twin, is assigned a separate decision module, which is designed to prepare a mobility offer of the vehicle and to transmit the prepared mobility offer in an automated manner to the decentralized consensus module for deployment as a smart contract within the distributed ledger technology (DLT).

6. The decentralized control system claimed in claim 4, wherein the decision module is designed to prepare the responding offer to the received mobility order or the mobility offer, taking into account a free-area detection of a loading space sensor of the associated vehicle, which is in particular represented by the digital twin.

7. The decentralized control system as claimed in claim, wherein the decision module is designed to prepare the responding offer to the received mobility order or the mobility offer, taking into account a free-weight detection of a load weight sensor of the associated vehicle, which is in particular represented by the digital twin.

8. The decentralized control system as claimed in claim, wherein the decision module is designed to prepare at least the responding offer to the received mobility order or the mobility offer, taking into account geolocation data and/or taking into account a current route planning, a current itinerary schedule and/or a current itinerary sequence of a navigation system of the associated vehicle, which is in particular represented by the digital twin.

9. The decentralized control system as claimed in claim, wherein the terminal forms at least part of an integrated vehicle-computer unit of the vehicle or at least part of a mobile computer that can be assigned to the vehicle.

10. The decentralized control system as claimed in claim, wherein the consensus module is designed to select at least one best offer from all received responding offers and to transmit a contract confirmation for the mobility order back to the vehicle with the selected responding offer.

11. The decentralized control system as claimed in claim 1, comprising a serverless infrastructure.

12. The decentralized control system as claimed in claim 1, wherein the consensus module is distributed in decentralized form over a plurality of terminals assigned to different vehicles, in particular integrated vehicle-computer units and/or mobile computers that can be assigned to the vehicles.

13. The decentralized control system as claimed in claim 12, wherein at least some of the terminals form distributed ledger technology (DLT) nodes.

14. A decentralized control method for the intra-fleet and/or inter-fleet, at least partially self-organized, control of a network formed at least by vehicles, in particular having a decentralized control system as claimed in claim 1, wherein in at least one method step mobility orders, in particular network-external or network-internal transport orders or service provision orders, and/or mobility offers, in particular internal transport offers or service provision offers, of vehicles of the network are transmitted to more than one terminal in the form of smart contracts within a distributed ledger technology (DLT), such as a directed acyclic graph (e.g. an IOTA tangle) or a blockchain, the terminals being assigned in each case to vehicles of the network.

15. The decentralized control method as claimed in claim 14, wherein in at least one method step, by at least one terminal which is assigned to an individual vehicle of the network a mobility offer is prepared and is transmitted to the decentralized consensus module for deployment as a smart contract within the distributed ledger technology (DLT).

16. The decentralized control method as claimed in claim 14, wherein in at least one method step, a mobility order is prepared by a further terminal and is transmitted by the further terminal to the decentralized consensus module for deployment as a smart contract within the distributed ledger technology (DLT).

17. The decentralized control method as claimed in claim 16, wherein in at least one method step, by terminals each of which is assigned to individual vehicles of the network, it is decided—based on an individual evaluation of an offer preparation target function for the respective assigned vehicle—whether, and in particular with which parameters, a responding offer to the mobility order will be submitted.

18. The decentralized control method as claimed in claim 17, wherein in at least one further method step a responding offer to the mobility order is prepared by the respective terminal.

19. The decentralized control method as claimed in claim 15 wherein for an evaluation of the offer preparation target function, for preparing the responding offer and/or for preparing the mobility offer, an available free area/free volume/capacity of the vehicle, an available free weight of the vehicle, a temporal availability of the vehicle, an already planned route, itinerary and/or itinerary sequence of the vehicle and/or geolocation data of the vehicle and/or the start and/or destination locations of the mobility order are considered.

20. The decentralized control method as claimed in claim 17 wherein in at least one further method step, all responding offers submitted by terminals assigned to different vehicles are evaluated by means of a contract target function of the smart contract, wherein at least one best offer is determined according to the criteria of the contract target function and wherein the contract is awarded at least to the vehicle having the terminal from which the best offer originates.

21. The decentralized control method as claimed in claim 20, wherein a combination of submitted responding offers is determined as the best offer and the contract is awarded to more than one vehicle.

22. The decentralized control method as claimed in claim 20, wherein in at least one method step, the mobility order is integrated in an automated manner into an updated route guidance, itinerary sequence and/or itinerary schedule of the vehicle/vehicles which are awarded the contract.

23. The decentralized control method as claimed in claim 20, wherein in at least one method step, a mobility order, for which a vehicle has already been awarded the contract, is forwarded by the terminal of the vehicle as a secondary mobility order.

24. The decentralized control method as claimed in claim 23, wherein the secondary mobility order, in the form of a smart contract within the distributed ledger technology (DLT), such as a directed acyclic graph (e.g. an IOTA Tangle) or a blockchain, is transmitted to terminals (18, 20) of more than one vehicle of the network.

25. The decentralized control method as claimed in claim 23, wherein the secondary mobility order is offered in a spot market for secondary mobility orders.
